(19) United States
(12) Patent Application Publication
(10) Pub. No.: US 2025/0015186 A1
(43) Pub. Date: Jan. 9, 2025

(54) Semiconductor structure

(71) Applicant: UNITED MICROELECTRONICS CORP., Hsin-Chu City (TW)

(72) Inventors: Hung-Chun Lee, Pingtung County (TW); Chih-Yi Wang, Tainan City (TW); Wei-Che Chen, Kaohsiung City (TW); Ya-Ting Hu, Kaohsiung City (TW); Yao-Jhan Wang, Tainan City (TW); Kun-Szu Tseng, Tainan City (TW); Feng-Yun Cheng, Kaohsiung City (TW); Shyan-Liang Chou, Tainan City (TW)

(73) Assignee: UNITED MICROELECTRONICS CORP., Hsin-Chu City (TW)

(21) Appl. No.: 18/227,299

(22) Filed: Jul. 27, 2023

(30) Foreign Application Priority Data
Jul. 4, 2023 (TW) 112124890

(51) Int. Cl. H01L 29/78; H01L 25/16

(52) U.S. Cl. CPC H01L 29/7851; H01L 25/16

(57) ABSTRACT

The invention provides a semiconductor structure, which comprises a middle/high voltage device region and a low voltage device region, a plurality of fin structures disposed in the low voltage device region, and a protruding part located at a boundary Between the middle/high voltage device region and the low voltage device region. A top surface of the protruding part is flat, and the top surface of the protruding part is aligned with a flat top surface of the middle/high voltage device region.

### BACKGROUND OF THE INVENTION

### 1. Field of the Invention

The invention relates to the field of semiconductor manufacturing, in particular to a structure generated at the boundary of a middle/high voltage device region and a low voltage device region in the semiconductor manufacturing.

### 2. Description of the Prior Art

In the semiconductor process, the fineness of the nano-process is generally described in nanometers. For example, the 14-nanometer process means that the lowest line width that can be formed in the semiconductor process is 14 nanometers. With the progress of process technology, the line width of nano-process is gradually reduced.

However, even with the progress of nano-process, not all devices are suitable for high-precision nano-process. For example, when the size of the device does not match the precision of the nano-process, it will not only lead to the decline of the yield of the device, but also consume more costs. Therefore, in order to adapt to components with different sizes or precisions, different components will be formed by nano-processes with different precisions.

On a chip, there may be components with different precisions in different regions at the same time, which may be formed by nano-processes with different precisions. Therefore, at the boundary of these regions, various structural problems may easily occur.

### SUMMARY OF THE INVENTION

The invention provides a semiconductor structure, which comprises a middle/high voltage device region, a low voltage device region, a plurality of fin structures, and a protruding part, wherein a top surface of the protruding part is flat, and the top surface of the protruding part is aligned with the flat top surface of the middle/high voltage device region.

The invention also provides a semiconductor structure, which comprises a middle/high voltage device region with a flat top surface.

A low voltage device region, which contains a plurality of fin structures, and a protruding sharp corner, which is located at a boundary Between the middle/high voltage device region and the low voltage device region, wherein a top surface of the protruding sharp corner is in a tip shape, and a top surface of the protruding sharp corner is lower than a flat top surface of the middle/high voltage device region.

The invention is characterized in that a protruding part or a sharp corner part is defined by a deep trench and a shallow trench at the boundary of a middle/high voltage device region (the applicable voltage is above 5 volts, preferably above 10 volts) and a low voltage device region (the applicable voltage is below 5 volts, preferably below 1.5 volts) on the same chip. This protruding part or sharp corner part can be used as a buffer between different regions to avoid the mutual influence of the two sides.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic view from above near a boundary Between a middle/high voltage device region and a low voltage device region of the present invention.

FIGS. 2 to 3 illustrate a semiconductor cross-sectional structure taken along the cross-sectional line A-A′ in FIG. 1 according to the first embodiment of the present invention.

FIG. 4 shows a cross-sectional structure of a semiconductor taken along the cross-sectional line A-A′ in FIG. 1 according to a second embodiment of the present invention.

FIG. 5 shows a cross-sectional structure of a semiconductor taken along the cross-sectional line A-A′ in FIG. 1 according to a third embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

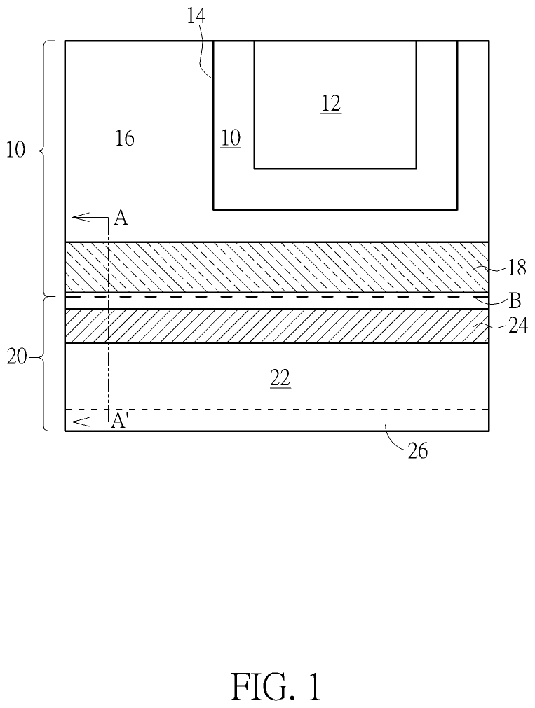

Please refer to FIG. 1, which shows a schematic view from above near a boundary between a middle/high voltage device region and a low voltage device region of the present invention. As shown in FIG. 1, the semiconductor structure 10 of the present invention includes a middle/high voltage device region 10 and a low voltage device region 20, with a boundary B between them. Among them, the middle/high voltage device region 10 and the low voltage device region 20 are different in operating voltages of elements contained therein. Generally speaking, taking a display chip as an example, the low voltage device region 20 includes, for example, a logic operation circuit, and its operating voltage is below 5 volts, preferably within 1.5 volts. On the contrary, the operating voltage of the electronic components contained in the middle/high voltage device region 10 is more than 5 volts, usually more than 10 volts. For example, a driving element in a display wafer needs a higher voltage to drive the elements therein, and these elements belong to the middle/high voltage elements of the present invention.

As mentioned in the prior art, different devices on the same chip may be formed by different precision nano-processes because of their different sizes or applications. In this embodiment, for example, the middle/high voltage devices or other related electronic devices (such as wires or trenches) in the middle/high voltage device region 10 are formed by a 22 nm process, while various low voltage devices (such as logic operation circuits) in the low voltage device region 20 require higher nano-precision, for example, by a 14 nm process. However, it should be noted that the above-mentioned 22 nm process or 14 nm process is only one example of the present invention, and the present invention is not limited to this.

When the nano-precision of semiconductor process is improved, it means that the size of devices is getting smaller and smaller, and devices can also develop towards three-dimensional structure to increase the density per unit area. In this embodiment, the low voltage device region 20 contains a plurality of fin structures (not shown in FIG. 1), while the middle/high voltage device region 10 is mainly planar. That is to say, the top view of the semiconductor structure shown in FIG. 1 can be regarded as the boundary between two regions respectively containing planar electronic components and regions containing three-dimensional electronic components, wherein the two regions are formed by different nano-precision processes.

Please continue to refer to FIG. 1. In the middle/high voltage device region 10, there are middle and high voltage devices 12 (such as the above-mentioned driving circuit), and a guard ring 14 may be included around the middle and high voltage devices 12 to prevent noise or stabilize voltage. The periphery of the guard ring 14 includes a dummy region 16, in which all devices included in the dummy region 16 are also formed by the 22 nm process, but the devices in the dummy region 16 will not be connected with other electronic devices. The dummy region 16 can be used as a buffer and located around the middle and high voltage devices 12 to protect the middle and high voltage devices 12 from the processes in other regions. In addition, a deep trench 18 is included in the middle/high voltage device region 10.

The low voltage device region 20 includes a dummy fin structure region 22, a shallow trench 24 and a fin structure region 26, the dummy fin structure region 22 is similar to the dummy region 16 in the middle/high voltage device region 10, and can be used for protecting electronic devices in the fin structure region 26. Both the dummy fin structure region 22 and the fin structure region 26 contain a plurality of fin structures therein. However, in the subsequent steps, only the fin structure in the fin structure region 26 will be made into electronic devices (such as transistors) and electrically connected with other devices. These features belong to the known technology in this field, so they will not be detailed here.

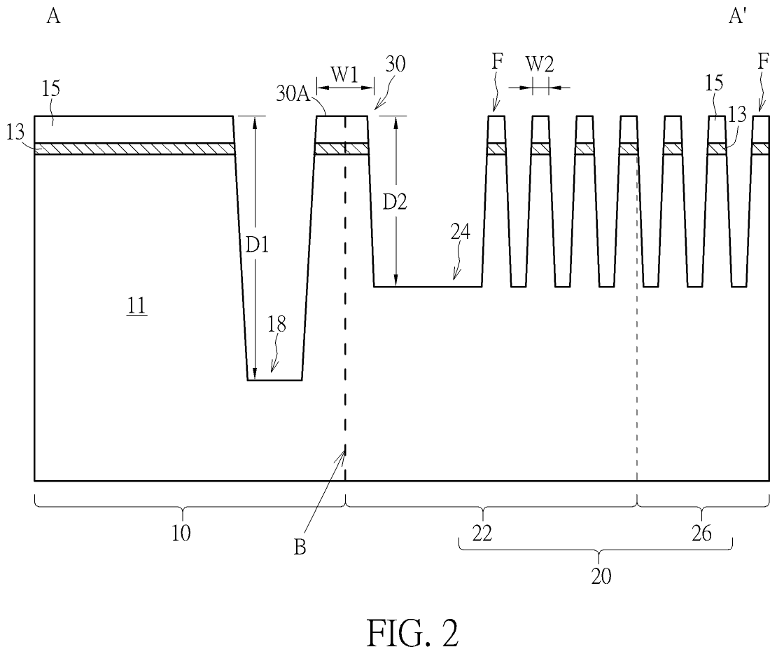

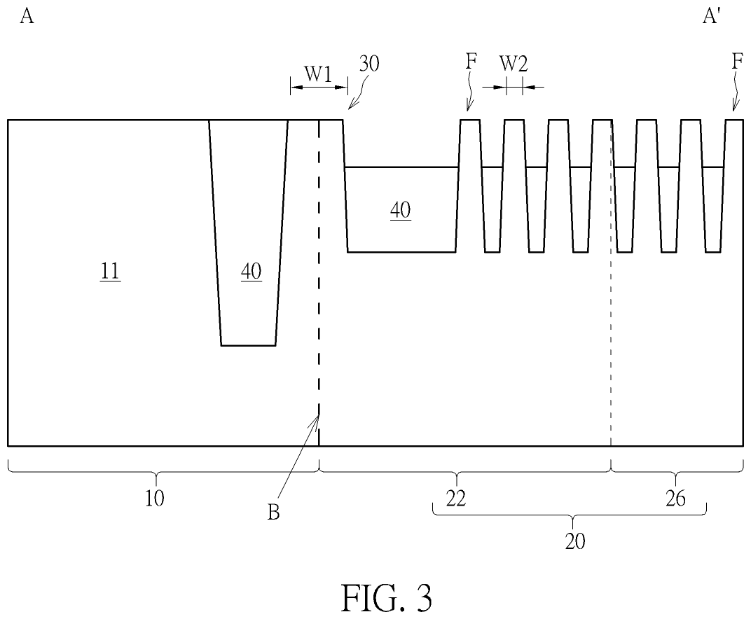

FIGS. 2-3 show the cross-sectional structure of the semiconductor taken along the cross-sectional line A-A′ in FIG. 1 according to the first embodiment of the present invention. As shown in FIG. 2, the substrate 11 includes a mask layer 13 and a mask layer 15, wherein the substrate 11 is made of silicon, and the mask layer 13 and the mask layer 15 are made of silicon oxide, silicon nitride or silicon oxynitride, etc. The present invention is not limited to this. The mask layer 13 and the mask layer 15 can be used to define the positions of grooves and fin structures, as a mask for etching steps, or as an etching stop layer for subsequent processes. Since the middle/high voltage device region 10 and the low voltage device region 20 are formed by semiconductor processes with different nanometer accuracy (precision), the depths of the deep trench 18 and the shallow trench 24 are also different. The deep trench 18 is used to define the formation range of middle and high voltage devices, and because the operating voltage of middle and high voltage devices is relative high, it necessary to be surround by the deep trench (that is, the deep trench 18) to achieve better isolation effect. On the contrary, since the shallow trench 24 may be made at the same time as the fin structure F, the depth of the shallow trench 24 may be the same as the bottom surface depth of the fin structure F. In this embodiment, the depth D1 of the deep trench 18 is about 2500 angstroms, and the depth D2 of the shallow trench 24 is about 1300 angstroms, but the present invention is not limited to this.

It is worth noting that a protruding part 30 is also included at the boundary between the middle/high voltage device region 10 and the low voltage device region 20 of the semiconductor structure of the present invention. In this embodiment, the protruding part 30 may have a flat top surface 30A, and the flat top surface 30A of the protruding part 30 is horizontally aligned with the flat top surface 10A of the surrounding middle/high voltage device region 10. The protruding part 30 is located between the deep trench 18 and the shallow trench 24, that is, the position defined by the deep trench 18 and the shallow trench 24. The protruding part 30 is also located at the boundary B between the middle/high voltage device region 10 and the low voltage device region 20, and can be used as a buffer structure between the two regions to avoid the interaction between the deep trench 18 and the shallow trench 24 in different regions. In this embodiment, the width W1 of the protruding part 30 is preferably greater than the width W2 of each fin structure F, but the present invention is not limited to this.

Next, an insulating layer 40 can be filled into the deep trench 18 and the shallow trench 24, the insulating layer 40 is preferably filled into the deep trench 18 and the shallow trench 24 first, and then part of the insulating layer 40 is removed by a planarization step (such as chemical mechanical polishing, CMP) and an etching back step, and the fin structure F of the low voltage device region 20 is exposed. Therefore, in the present invention, the height of the insulating layer 40 in the middle/high voltage device region 10 is different from the height of the insulating layer 40 in the low voltage device region 20, for example, the top surface of the insulating layer 40 in the middle/high voltage device region 10 is higher than the top surface of the insulating layer 40 in the low voltage device region 20. In addition, in this embodiment, the mask layer 13 and the mask layer 15 are removed simultaneously after the planarization step and the etching back step.

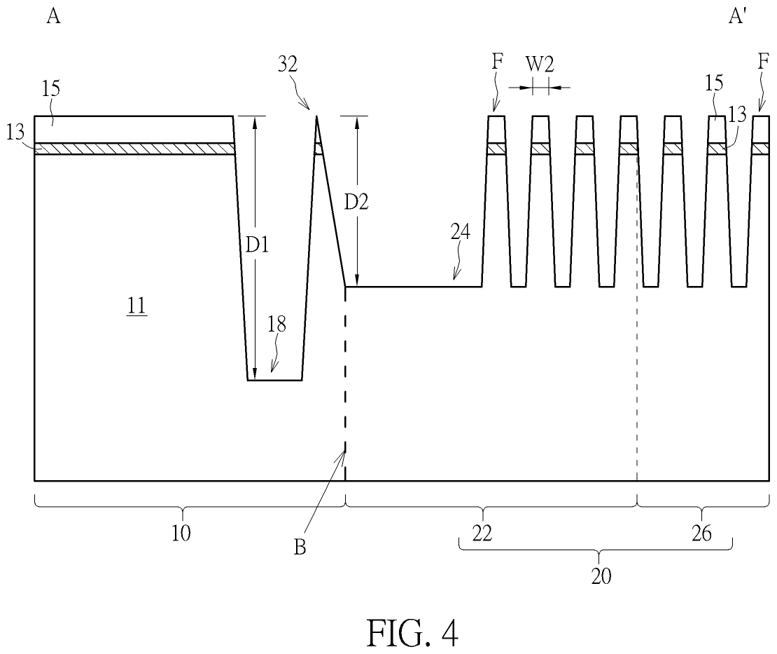

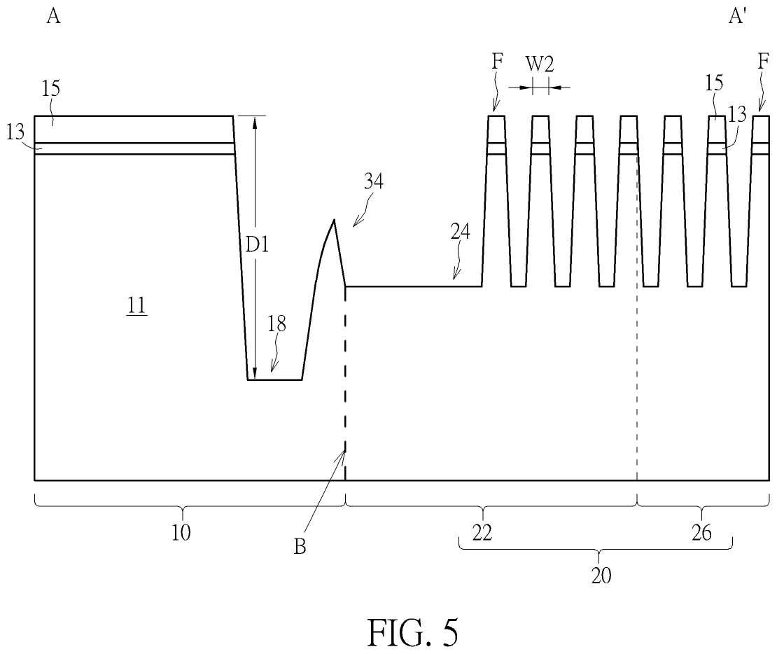

FIG. 4 shows a cross-sectional structure of a semiconductor taken along the cross-sectional line A-A′ in FIG. 1 according to a second embodiment of the present invention. FIG. 5 shows a cross-sectional structure of a semiconductor taken along the cross-sectional line A-A′ in FIG. 1 according to a third embodiment of the present invention. In different embodiments of the present invention, the shape of the protruding part will be influenced by the change of etching parameters during the fabrication of the deep trench 18 and the shallow trench 24. In some embodiments, as shown in FIG. 4, the original protruding part is etched to form a sharp corner part 32, where the sharp corner part 32 does not contain a flat top surface, but a tip top surface. However, in this embodiment, the top surface of the sharp corner part 32 is substantially aligned with the flat top surface 10A of the middle/high voltage device region 10 in the horizontal direction. Or in another embodiment of the present invention, as shown in FIG. 5, the protruding part may be etched more to form a sharp corner part 34, wherein the height of the sharp corner part 34 is also lower than the flat top surface 10A of the surrounding middle/high voltage device region 10 or lower than the top surface of the fin structure F. Such variations are also within the scope of the present invention. In addition, in these embodiments, an insulating layer will be formed to fill the deep trench 18 and the shallow trench 24, which will not be repeated here.

Based on the above description and drawings, the present invention provides a semiconductor structure, which includes a middle/high voltage device region 10, a low voltage device region 20 with a plurality of fin structures F therein, and a protruding part 30 located at a boundary B between the middle/high voltage device region 10 and the low voltage device region 20, wherein a top surface 30A of the protruding part 30 is flat, and the top surface 30A of the protruding part 30 and the flat top surface 10A of the middle/high voltage device region 10 are aligned with each other.

In some embodiments of the present invention, a deep trench 18 is further included, which is located in the middle/high voltage device region 10 and adjacent to the protruding part 30.

In some embodiments of the present invention, a shallow trench 24 is included and located in the low voltage device region 20, and the shallow trench 24 is adjacent to the protruding part 30.

In some embodiments of the present invention, a depth D1 of the deep trench 24 is greater than a depth D2 of the shallow trench 24.

In some embodiments of the present invention, a bottom surface of each fin structure Fis aligned with a bottom surface of the shallow trench 24 (as shown in FIG. 2).

In some embodiments of the present invention, a width W1 of the protruding part 30 is larger than a width W2 of each fin structure F when viewed from a cross section.

In some embodiments of the present invention, the middle/high voltage device region 10 contains a plurality of first elements (i.e., middle and high voltage elements 12), a driving voltage of each first element 12 is greater than 10 volts, and the low voltage device region 20 contains a plurality of second elements (i.e., electronic elements formed in the subsequent fin structure region 26), and a driving voltage of each second element is less than 1.5 volts.

In some embodiments of the present invention, each first element 12 comprises a display driving wafer.

In some embodiments of the present invention, each second element (electronic element formed in the subsequent fin structure region 26) includes a transistor element for logic operation.

In some embodiments of the present invention, each first device and each second device are made by nano-processes with different precisions (for example, in one embodiment, the first device is formed by a 22-nanometer process and the second device is formed by a 14-nanometer process).

The present invention also provides a semiconductor structure, which comprises a middle/high voltage device region 10, a low voltage device region 20, a plurality of fin structures F located therein, and a protruding sharp corner 34 located at a boundary B between the middle/high voltage device region 10 and the low voltage device region 20, wherein a top surface of the protruding sharp corner 34 is in a sharp shape, and a top surface of the protruding sharp corner 32 is lower than the flat top surface 10A of the middle/high voltage device region 10 (as shown in FIG. 5).

In some embodiments of the present invention, the middle/high voltage device region 10 mainly contains planar electronic elements, so it can also be regarded as a planar device region, whereas the low voltage device region 20 mainly contains fin structures, so it can be regarded as a fin structure device region.

Therefore, in some embodiments of the present invention, a semiconductor structure is provided, which includes a planar device region (i.e., the middle/high voltage device region 10) including a flat top surface 10A, a fin structure device region (i.e., the low voltage device region 20) including a plurality of fin structures F therein, and a protruding part 30 located at a boundary B between the planar device region 10 and the fin structure device region 20, wherein a top surface 30A of the protruding part 30 is flat, and the top surface 30A of the protruding part 30 is aligned with the flat top surface 10A of the planar device region 10.

In some embodiments of the present invention, a semiconductor structure is provided, which includes a planar device region 10 including a flat top surface 10A, a fin structure device region 20 including a plurality of fin structure structures F therein, and a protruding sharp corner 34 located at a boundary B between the planar device region 10 and the fin structure device region 20, wherein a top surface of the protruding sharp corner 34 is in a sharp shape, and a top surface of the protruding sharp corner 34 is lower than that of the planar device region 10.

The invention is characterized in that a protruding part or a sharp corner part is defined by a deep trench and a shallow trench at the boundary of a middle/high voltage device region (the applicable voltage is above 5 volts, preferably above 10 volts) and a low voltage device region (the applicable voltage is below 5 volts, preferably below 1.5 volts) on the same chip. This protruding part or sharp corner part can be used as a buffer between different regions to avoid the mutual influence of the two sides.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising:
a middle/high voltage device region including a flat top surface;
a low voltage device region including a plurality of fin structures therein; and
a protruding part is located at the boundary of the middle/high voltage device region and the low voltage device region, wherein a top surface of the protruding part is flat, and the top surface of the protruding part is aligned with the flat top surface of the middle/high voltage device region.

2. The semiconductor structure according to claim 1, further comprising a deep trench located in the middle/high voltage device region and adjacent to the protruding part.

3. The semiconductor structure according to claim 2, further comprising a shallow trench located in the low voltage device region and adjacent to the protruding part.

4. The semiconductor structure according to claim 3, wherein a depth of the deep trench is greater than a depth of the shallow trench.

5. The semiconductor structure according to claim 3, wherein a bottom surface of each fin structure is aligned with a bottom surface of the shallow trench.

6. The semiconductor structure according to claim 1, wherein a width of the protruding part is larger than a width of each fin structure when viewed from a sectional view.

7. The semiconductor structure according to claim 1, wherein the middle/high voltage device region contains a plurality of first elements, each of the first elements has a driving voltage greater than 10 volts, and the low voltage device region contains a plurality of second elements, each of the second elements has a driving voltage less than 1.5 volts.

8. The semiconductor structure according to claim 7, wherein each of the first elements comprises a display driving chip.

9. The semiconductor structure according to claim 7, wherein each of the second elements comprises a transistor element for logic operation.

10. The semiconductor structure according to claim 7, wherein each of the first elements and each of the second elements are fabricated by nanometer processes with different precisions.

11. A semiconductor structure comprising:
a middle/high voltage device region including a flat top surface;
a low voltage device region including a plurality of fin structures therein; and
a protruding sharp corner is located at a boundary Between the middle/high voltage device region and the low voltage device region, wherein a top surface of the protruding sharp corner is in a tip shape, and a top surface of the protruding sharp corner is lower than the flat top surface of the middle/high voltage device region.

12. The semiconductor structure according to claim 11, further comprising a deep trench located in the middle/high voltage device region and adjacent to the protruding sharp corner.

13. The semiconductor structure according to claim 12, further comprising a shallow trench located in the low voltage device region and adjacent to the protruding sharp corner.

14. The semiconductor structure according to claim 13, wherein a depth of the deep trench is greater than a depth of the shallow trench.

15. The semiconductor structure according to claim 13, wherein a bottom surface of each fin structure is aligned with a bottom surface of the shallow trench.

16. The semiconductor structure according to claim 11, wherein a width of the protruding sharp corner is larger than a width of each fin structure when viewed from a sectional view.

17. The semiconductor structure according to claim 11, wherein the middle/high voltage device region contains a plurality of first elements, each of which has a driving voltage greater than 10 volts, and the low voltage device region contains a plurality of second elements, each of which has a driving voltage less than 1.5 volts.

18. The semiconductor structure according to claim 17, wherein each of the first elements and each of the second elements are fabricated by nanometer processes with different precisions.

19. A semiconductor structure comprising:
a planar device region including a flat top surface;
a fin structure device region, which contains a plurality of fin structures; and
a protruding part, located at a boundary of the planar device region and the fin structure device region, wherein a top surface of the protruding part is flat and is aligned with the flat top surface of the planar device region.

20. A semiconductor structure comprising:
a planar device region including a flat top surface;
a fin structure device region, which contains a plurality of fin structures; and
a protruding sharp corner located at a boundary Between the planar device region and the fin structure device region, wherein a top surface of the protruding sharp corner is in a tip shape and is lower than the flat top surface of the planar device region.
